(19) United States
(12) Patent Application Publication
(10) Pub. No.: US 2025/0287773 A1
(43) Pub. Date: Sep. 11, 2025

(54) ORGANIC LIGHT-EMITTING DEVICE AND DISPLAY PANEL

(71) Applicant: Kunshan New Flat Panel Display Technology Center Co., Ltd., Kunshan (CN)

(72) Inventors: Yu GAO, Kunshan (CN); Ruicong ZHOU, Kunshan (CN); Rubo XING, Kunshan (CN); Xianrui QIAN, Kunshan (CN)

(73) Assignee: Kunshan New Flat Panel Display Technology Center Co., Ltd., Kunshan (CN)

(21) Appl. No.: 19/219,993

(22) Filed: May 27, 2025

Related U.S. Application Data
(63) Continuation of application No. PCT/CN2023/079132, filed on Mar. 1, 2023.

(30) Foreign Application Priority Data
Nov. 28, 2022 (CN) 202211499600.8

(51) Int. Cl. H10K 50/12; H10K 50/15; H10K 50/18; H10K 101/25; H10K 101/40

(52) U.S. Cl. CPC H10K 50/12; H10K 50/15; H10K 50/181; H10K 2101/25; H10K 2101/40

(57) ABSTRACT

Provided in the embodiments of the present application are an organic light-emitting device and a display panel. The organic light-emitting device includes a hole transport layer and a light-emitting layer which are stacked, the energy level difference between the HOMO energy level of at least one material of the hole transport layer and the HOMO energy level of at least one material of the light-emitting layer being less than or equal to 0.3 eV.

### CROSS-REFERENCE TO RELATED APPLICATIONS

The present application a continuation of International Application No. PCT/CN 2023/079132, filed on Mar. 1, 2023, which claims priority to Chinese Patent Application No. 202211499600.8, filed on Nov. 28, 2022. All of the aforementioned patent applications are hereby incorporated by reference in their entireties.

### FIELD

The present application relates to the field of display equipment, and specifically to an organic light-emitting device and a display panel.

### BACKGROUND

Organic light-emitting diodes (OLEDs) are active light-emitting devices. Compared with a conventional liquid crystal display (LCD) method, OLED display technology does not require a backlight and has self-luminous properties. The OLEDs use a thin film layer of an organic material and a glass substrate, and when there is a current passed, the organic material may emit light. Therefore, OLED display panels can significantly save electric energy and be made lighter and thinner, tolerate a wider range of temperature changes than LCD display panels, and have a wider viewing angle. The OLED display panels are expected to become the next generation of flat panel display technology after LCD, and it is currently one of the flat panel display technologies that have attracted most attention.

An OLED display panel includes light-emitting units and a driving circuit for driving the light-emitting units to emit light. Different light-emitting units may lead to different times required for the light-emitting units to be turned on. Consequently, when the display panel is turned on, ghosting occurs in the first frame, which affects the display effect of the display panel.

### SUMMARY

Embodiments of the present application provide an organic light-emitting device and a display panel, with a view to improving the display effect of the display panel.

An embodiment of a first aspect of the present application provides an organic light-emitting device, including a hole transport layer and a light-emitting layer that are arranged in a stacked manner, where an energy level difference between a HOMO energy level of at least one material in the hole transport layer and a HOMO energy level of at least one material in the light-emitting layer is less than or equal to 0.3 eV.

An embodiment of a second aspect of the present application further provides a display panel, including an organic light-emitting device according to any one of the above embodiments of the first aspect.

In the organic light-emitting device provided in the embodiment of the present application, the organic light-emitting device includes the hole transport layer and the light-emitting layer, and the light-emitting layer is configured to emit light to implement display of the display panel. In the light-emitting layer and the hole transport layer, since the energy level difference between the HOMO energy level of the at least one material in the hole transport layer and the HOMO energy level of the at least one material in the light-emitting layer is less than or equal to 0.3 eV, the energy level difference between the HOMO energy level of the hole transport layer and the HOMO energy level of the light-emitting layer is small, and the capacitance formed between the hole transport layer and the light-emitting layer is low, thereby effectively reducing charge accumulation between the hole transport layer and the light-emitting layer, and reducing differences in capacitance between the light-emitting layers and the hole transport layers in different organic light-emitting devices. When a plurality of organic light-emitting devices are used in the display panel, differences in the time required for different organic light-emitting devices to be turned on can be reduced, and first frame display problems of the first frame color shift and the insufficient first frame brightness can be effectively mitigated, and thus, the display effect of the display panel can be improved.

### BRIEF DESCRIPTION OF THE DRAWINGS

FIG. 1 is a schematic diagram of a layer structure of a display panel according to an embodiment of the present application;

FIG. 2 is a schematic diagram of a layer structure of a display panel according to another embodiment of the present application;

FIG. 3 is a schematic diagram of energy levels of part of a layer structure of a light-emitting unit in a display panel according to an embodiment of the present application; and

FIG. 4 is a graph of capacitance-voltage curves for some example display panels according to the present application.

### DETAILED DESCRIPTION OF THE EMBODIMENTS

The inventors have found that in an OLED display panel, the capacitance formed inside a light-emitting unit in the OLED display panel may affect the charging time of the light-emitting unit, thereby affecting the brightness of the light-emitting unit in the first frame, and thus, affecting the display effect of the display panel in the first frame. For example, when light-emitting units of different colors have different capacitances, the time required for the light-emitting units of different colors to be turned on in the first frame may be affected, and the brightness ratio of the light-emitting units of different colors in the first frame may be affected to change, leading to problems of the first frame color shift and the insufficient first frame brightness.

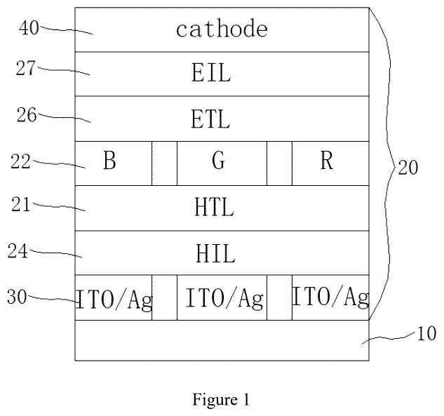

To solve the above problems, the present application is provided. In order to better understand the present application, a display panel and an organic light-emitting device according to the embodiments of the present application will be described in detail below with reference to FIGS. 1 to 4.

As shown in FIG. 1, a display panel according to the present application includes a substrate 10 and an organic light-emitting device 20 arranged on the substrate 10.

The organic light-emitting device 20 is arranged in a variety of manners. In some embodiments, the organic light-emitting device 20 includes a hole transport layer 21 and a light-emitting layer 22 that are arranged in a stacked manner, where an energy level difference between a HOMO energy level of at least one material in the hole transport layer 21 and a HOMO energy level of at least one material in the light-emitting layer 22 is less than or equal to 0.3 eV. In one or more embodiments, when the organic light-emitting device 20 is used in a display panel, the hole transport layer 21 and the light-emitting layer 22 may be sequentially arranged in a stacked manner in a direction away from the substrate 10.

In this embodiment, the organic light-emitting device 20 includes a hole transport layer 21 and a light-emitting layer 22, and the light-emitting layer 22 is configured to emit light to implement display of the display panel. In the light-emitting layer 22 and the hole transport layer 21, an energy level difference between a HOMO energy level of at least one material in the hole transport layer 21 and a HOMO energy level of at least one material in the light-emitting layer 22 is less than or equal to 0.3 eV. Therefore, the energy level difference between the HOMO energy level of the hole transport layer 21 and the HOMO energy level of the light-emitting layer 22 is small, and the capacitance formed between the hole transport layer 21 and the light-emitting layer 22 is low, thereby effectively reducing charge accumulation between the hole transport layer 21 and the light-emitting layer 22, and reducing differences in capacitance between the light-emitting layers 21 and the hole transport layers 22 in different light-emitting devices 20. When a plurality of organic light-emitting devices 20 are used in the display panel, differences in the time required for the light-emitting layers 22 of different light-emitting devices 20 to be turned on can be reduced, the problems of the first frame color shift and the insufficient first frame brightness in organic light-emitting devices 20 of different colors can be effectively mitigated, and thus, the display effect of the display panel can be improved.

In one or more embodiments, the organic light-emitting device 20 may be at least one of a red organic light-emitting device, a green organic light-emitting device, and a blue organic light-emitting device, where the red organic light-emitting device, the green organic light-emitting device, and the blue organic light-emitting device may all include the hole transport layer 21 and the light-emitting layer 22 described above, and the hole transport layer 21 and the light-emitting layer 22 of at least one of the red organic light-emitting device, the green organic light-emitting device, and the blue organic light-emitting device satisfy a condition as follows: an energy level difference between a HOMO energy level of at least one material in the hole transport layer 21 and a HOMO energy level of at least one material in the light-emitting layer 22 is less than or equal to 0.3 eV.

In one or more embodiments, when a plurality of red organic light-emitting devices, a plurality of green organic light-emitting devices, and a plurality of blue organic light-emitting devices are provided in a display panel, the light-emitting layers 22 of the red organic light-emitting devices, the green organic light-emitting devices, and the blue organic light-emitting devices are separated from each other and are different from each other, and the hole transport layers 21 of the red organic light-emitting devices, the green organic light-emitting devices, and the blue organic light-emitting devices may be connected to each other.

In one or more embodiments, a green organic light-emitting device includes the hole transport layer 21 and the light-emitting layer 22 described above, and the hole transport layer 21 and the light-emitting layer 22 of the green organic light-emitting device satisfy a condition as follows: an energy level difference between a HOMO energy level of at least one material in the hole transport layer 21 and a HOMO energy level of at least one material in the light-emitting layer 22 is less than or equal to 0.3 eV.

The inventors have found through research that green organic light-emitting devices are more prone to a problem of the red color shift of the entire display panel due to the turning-on delay of the first frame or the insufficient first frame luminance. In some embodiments of the present application, the hole transport layer 21 and the light-emitting layer 22 of the green organic light-emitting device satisfy a condition as follows: an energy level difference between a HOMO energy level of at least one material in the hole transport layer 21 and a HOMO energy level of at least one material in the light-emitting layer 22 is less than or equal to 0.3 eV. Therefore, the capacitance between the hole transport layer 21 and the light-emitting layer 22 of the green organic light-emitting device is small, thereby effectively reducing charge accumulation between the hole transport layer 21 and the light-emitting layer 22, reducing the time required for the green light-emitting device 20 to be turned on, and the problem of the red color shift of first frame display of the display panel is mitigated.

In one or more embodiments, the hole transport layer 21 is prepared and formed from a same material, and the light-emitting layer 22 is prepared and formed from a same material. Then, an energy level difference between a HOMO energy level of at least one material in the hole transport layer 21 and a HOMO energy level of at least one material in the light-emitting layer 22 being less than or equal to 0.3 eV is that an energy level difference between a HOMO energy level of the material in the hole transport layer 21 and a HOMO energy level of the material in the light-emitting layer 22 is less than or equal to 0.3 eV.

In some other embodiments, the hole transport layer 21 is formed from a mixture of more than two materials, and the light-emitting layer 22 is formed from a mixture of more than two materials. In the embodiments of the present application, it is sufficient that a difference between a HOMO energy level of at least one material in the hole transport layer 21 and a HOMO energy level of at least one material in the light-emitting layer 22 is less than or equal to 0.3 eV. For example, an energy level difference between a HOMO energy level of one material in the hole transport layer 21 and a HOMO energy level of one material in the light-emitting layer 22 is less than or equal to 0.3 eV; or energy level differences between a HOMO energy level of one material in the hole transport layer 21 and HOMO energy levels of a plurality of materials in the light-emitting layer 22 are less than or equal to 0.3 eV; or energy level differences between HOMO energy levels of a plurality of materials in the hole transport layer 21 and a HOMO energy levels of one material in the light-emitting layer 22 are less than or equal to 0.3 eV; or energy level differences between HOMO energy levels of a plurality of materials in the hole transport layer 21 and HOMO energy levels of a plurality of materials in the light-emitting layer 22 are less than or equal to 0.3 eV.

In one or more embodiments, an energy level difference between a HOMO energy level of the hole transport layer 21 and a HOMO energy level of the light-emitting layer 22 is less than or equal to 0.3 eV, that is, an energy level difference between an overall HOMO energy level of materials in the hole transport layer 21 and an overall HOMO energy level of materials in the light-emitting layer 22 is less than or equal to 0.3 eV, thereby better reducing charge accumulation between the hole transport layer 21 and the light-emitting layer 22.

In one or more embodiments, the organic light-emitting device 20 further includes a hole injection layer 24, where the hole injection layer 24 is located on a side of the hole transport layer 21 away from the light-emitting layer 22. In one or more embodiments, the organic light-emitting device 20 further includes an electron transport layer 26 and an electron injection layer 27 that are sequentially arranged in a stacked manner on a side of the light-emitting layer 22 away from the hole transport layer 21.

In one or more embodiments, the organic light-emitting device 20 further includes a first electrode 30 and a second electrode 40, where one of the first electrode 30 and the second electrode 40 is located on a side of the hole injection layer 24 away from the hole transport layer 21, and the other is located on a side of the electron injection layer 27 away from the electron transport layer 26. The first electrode 30 and the second electrode 40 are used for driving the light-emitting layer 22 to emit light. The first electrode 30 may, for example, be an anode, and the second electrode 40 may, for example, be a cathode, where the anode is arranged on the substrate 10.

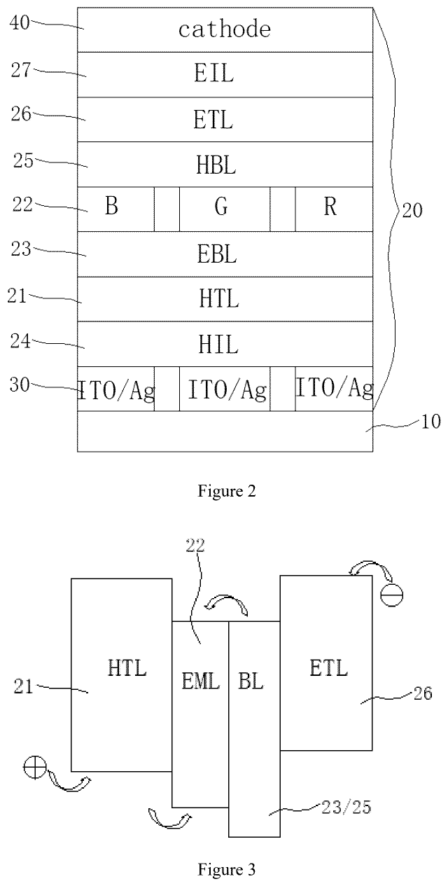

In one or more embodiments, as shown in FIGS. 2 and 3, an organic light-emitting device 20 further includes blocking layers, which may include an electron blocking layer 23 or a hole blocking layer 25, or an electron blocking layer 23 and a hole blocking layer 25. For example, the hole blocking layer 25 may be arranged between the electron transport layer 26 and the light-emitting layer 22 to block transport of holes toward the electron transport layer 26. The electron blocking layer 23 may be arranged between the hole transport layer 21 and the light-emitting layer 22 to block transport of electrons toward the hole transport layer 21.

In one or more embodiments, the hole injection layer 24, the hole transport layer 21, the electron blocking layer 23 (if any), the hole blocking layer 25 (if any), the electron transport layer 26, and the electron injection layer 27 may be an entire layer structure, that is, the hole injection layers, the hole transport layers 21, the electron blocking layers 23 (if any), the hole blocking layers 25 (if any), the electron transport layers 26, and the electron injection layers 27 of adjacent two light-emitting devices 20 are connected to each other as a common layer.

In one or more embodiments, as shown in FIG. 3, HOMO energy levels of the hole transport layer 21, the light-emitting layer 22, the blocking layer, and the electron transport layer 26 are shown in FIG. 3. Lower edges of the hole transport layer 21, the light-emitting layer 22, the blocking layer, and the electron transport layer 26 represent the HOMO energy levels.

In one or more embodiments, as shown in FIG. 2, the organic light-emitting device 20 further includes the electron blocking layer 23, where the electron blocking layer 23 is located between the hole transport layer 21 and the light-emitting layer 22.

In one or more embodiments, the electron blocking layer arranged between the hole transport layer 21 and the light-emitting layer 22 can block electrons overflowing from the light-emitting layer 22, and combination of these electrons with holes at locations other than the light-emitting layer 22 is reduced, thereby improving the display effect of the display panel.

In one or more embodiments, there is a first difference E1 between a HOMO energy level of at least one material in the hole transport layer 21 and a HOMO energy level of at least one material in the electron blocking layer 23; and there is a second difference E2 between a HOMO energy level of at least one material in the electron blocking layer 23 and a HOMO energy level of at least one material in the light-emitting layer 22, where the first difference E1 is greater than the second difference E2.

In one or more embodiments, the electron blocking layer 23 is closer to the light-emitting layer 22, and the HOMO energy level difference between the electron blocking layer 23 and the light-emitting layer 22 is more likely to affect the time required for the organic light-emitting device 20 to be turned on. The difference between the HOMO energy level of the at least one material in the hole transport layer 21 and the HOMO energy level of the at least one material in the electron blocking layer 23 is greater than the difference between the HOMO energy level of the at least one material in the electron blocking layer 23 and the HOMO energy level of the at least one material in the light-emitting layer 22. That is, the difference between the HOMO energy level of the at least one material in the electron blocking layer 23 and the HOMO energy level of the at least one material in the light-emitting layer 22 is smaller, and the HOMO energy level of the at least one material in the electron blocking layer 23 is closer to the HOMO energy level of the at least one material in the light-emitting layer 22, thereby effectively reducing the capacitance between the electron blocking layer 23 and the light-emitting layer 22, reducing charge accumulation between the electron blocking layer 23 and the light-emitting layer 22, and the problem of turning-on delay of the organic light-emitting device 20 is mitigated.

In one or more embodiments, the first difference E1 is a difference between a HOMO energy level of at least one material in the hole transport layer 21 and a HOMO energy level of at least one material in the electron blocking layer 23. Specifically, the first difference E1 is a difference between a HOMO energy level of one material in the hole transport layer 21 and a HOMO energy level of one material in the electron blocking layer 23; or the first difference E1 is differences between a HOMO energy level of one material in the hole transport layer 21 and HOMO energy levels of a plurality of materials in the electron blocking layer 23; or the first difference E1 is differences between HOMO energy levels of a plurality of materials in the hole transport layer 21 and a HOMO energy level of one material in the electron blocking layer 23; or the first difference E1 is differences between HOMO energy levels of a plurality of materials in the hole transport layer 21 and HOMO energy levels of a plurality of materials in the electron blocking layer 23.

Likewise, the second difference E2 may also be a difference between a HOMO energy level of one or more materials in the electron blocking layer 23 and a HOMO energy level of one or more materials in the light-emitting layer 22.

In one or more embodiments, the first difference E1 is a difference between an overall HOMO energy level of the hole transport layer 21 and an overall HOMO energy level of the electron blocking layer 23, and the second difference E2 is a difference between the overall HOMO energy level of the electron blocking layer 23 and an overall HOMO energy level of the light-emitting layer 22. As such, the overall HOMO energy level of the electron blocking layer 23 is closer to the overall HOMO energy level of the light-emitting layer 22, thereby reducing hole accumulation between the electron blocking layer 23 and the light-emitting layer 22, and the problem of turning-on delay of the organic light-emitting device 20 is better mitigated.

In one or more embodiments, the light-emitting layer 22 includes a P-type material, and there is the second difference E2 between the HOMO energy level of the at least one material in the electron blocking layer 23 and a HOMO energy level of the P-type material in the light-emitting layer 22.

In one or more embodiments, the second difference E2 is the HOMO energy level difference between the material in the electron blocking layer 23 and the P-type material in the light-emitting layer 22. The P-type material in the light-emitting layer 22 is used for transporting holes, and the P-type material in the light-emitting layer 22 is more likely to form a capacitance with the electron blocking layer 23. When the HOMO energy level difference between the material in the electron blocking layer 23 and the P-type material in the light-emitting layer 22 is small, the capacitance between the electron blocking layer 23 and the light-emitting layer 22 is small, thereby better mitigating the problem of turning-on delay of the organic light-emitting device 20.

In one or more embodiments, at least one material in the electron blocking layer 23 and at least one material in the hole transport layer 21 or the light-emitting layer 22 both include a specified molecular group.

In one or more embodiments, at least one material in the electron blocking layer 23 and at least one material in the hole transport layer 21 and the light-emitting layer 22 both include a specified molecular group.

For example, the at least one material in the hole transport layer 21 and the at least one material in the electron blocking layer 23 both include a specified molecular group, that is, a molecular group of the at least one material in the hole transport layer 21 is the same as a molecular group of the at least one material in the electron blocking layer 23.

In one or more embodiments, since the molecular group of the at least one material in the hole transport layer 21 is the same as the molecular group of the at least one material in the electron blocking layer 23, the transport rate of holes between the hole transport layer 21 and the electron blocking layer 23 can be increased, and hole accumulation between the hole transport layer 21 and the electron blocking layer 23 can be reduced, thereby enabling faster hole transport to the light-emitting layer 22, and the problem that turning-on of the organic light-emitting device 20 is liable to delay is better mitigated.

In one or more embodiments, it is possible that one or more materials in the hole transport layer 21 and one or more materials in the electron blocking layer 23 include the specified molecular group described above.

In one or more embodiments, at least one material in the light-emitting layer 22 and at least one material in the electron blocking layer 23 both include a specified molecular group, that is, a molecular group of the at least one material in the electron blocking layer 23 is the same as a molecular group of the at least one material in the light-emitting layer 22.

In one or more embodiments, since the molecular group of the at least one material in the electron blocking layer 23 is the same as the molecular group of the at least one material in the light-emitting layer 22, the transport rate of holes between the electron blocking layer 23 and the light-emitting layer 22 can be increased, and hole accumulation between the electron blocking layer 23 and the light-emitting layer 22 can be reduced, thereby enabling faster hole transport to the light-emitting layer 22, and the problem that turning-on of the organic light-emitting device 20 is liable to delay is better mitigated.

In one or more embodiments, it is possible that one or more materials in the electron blocking layer 23 and one or more materials in the light-emitting layer 22 both include a specified molecular group.

In still some embodiments, at least one material in the hole transport layer 21, at least one material in the electron blocking layer 23, and at least one material in the light-emitting layer 22 all include a specified molecular group. That is, a molecular group of the at least one material in the hole transport layer 21, a molecular group of the at least one material in the electron blocking layer 23, and a molecular group of the at least one material in the light-emitting layer 22 are the same.

In one or more embodiments, since the molecular group of the at least one material in the hole transport layer 21, the molecular group of the at least one material in the electron blocking layer 23, and the molecular group of the at least one material in the light-emitting layer 22 are the same, the transport rate of holes between the hole transport layer 21, the electron blocking layer 23, and the light-emitting layer 22 can be increased, and hole accumulation between the hole transport layer and the electron blocking layer 23 or between the electron blocking layer 23 and the light-emitting layer 22 can be reduced, thereby enabling faster hole transport to the light-emitting layer 22, and the problem that turning-on of the organic light-emitting device 20 is liable to delay is better mitigated.

In one or more embodiments, since the molecular group of the at least one material in the hole transport layer 21, the molecular group of the at least one material in the electron blocking layer 23, and the molecular group of the at least one material in the light-emitting layer 22 are the same, the transport rate of holes between the hole transport layer 21, the electron blocking layer 23, and the light-emitting layer 22 can be increased, and hole accumulation between the hole transport layer and the electron blocking layer 23 and between the electron blocking layer 23 and the light-emitting layer 22 can be reduced, thereby enabling faster hole transport to the light-emitting layer 22, and the problem that turning-on of the organic light-emitting device 20 is liable to delay is better mitigated.

In one or more embodiments, it is possible that one or more materials in the hole transport layer 21, one or more materials in the electron blocking layer 23, and one or more materials in the light-emitting layer 22 all include the specified molecular group described above.

In one or more embodiments, the specified molecular group described above may include at least one of fluorene and derivatives thereof, triarylamine and derivatives thereof, carbazole and derivatives thereof, and heterocyclic derivatives.

In one or more embodiments, the light-emitting layer 22 includes a P-type material, and the at least one material in the electron blocking layer 23 and the P-type material in the light-emitting layer 22 both include the specified molecular group described above. That is, a molecular group of the at least one material in the electron blocking layer 23 is the same as a molecular group of the P-type material in the light-emitting layer 22.

In one or more embodiments, the P-type material in the light-emitting layer 22 is used for transporting holes, since the molecular group of the at least one material in the electron blocking layer 23 is the same as the molecular group of the P-type material in the light-emitting layer 22, the transport rate of holes between the electron blocking layer 23 and a hole layer can be better increased, and hole accumulation between the electron blocking layer 23 and the light-emitting layer 22 can be reduced, thereby enabling faster hole transport to the light-emitting layer 22, and the problem that turning-on of the organic light-emitting device 20 is liable to delay is better mitigated.

In one or more embodiments, when the light-emitting layer 22 includes the P-type material, a molecular group of at least one material in the hole transport layer 21, a molecular group of at least one material in the electron blocking layer 23 are the same as a molecular group of the P-type material in the light-emitting layer 22. Therefore, the transport rates of holes between the hole transport layer 21 and the electron blocking layer 23, and between the electron blocking layer 23 and the light-emitting layer 22 can be further increased, thereby enabling faster hole transport to the light-emitting layer 22, and the problem that turning-on of the organic light-emitting device 20 is liable to delay is better mitigated.

In one or more embodiments, a material in the electron blocking layer 23 and a material in the light-emitting layer 22 do not form an exciplex, and the transport rate of holes is increased.

In one or more embodiments, at least one material in the electron blocking layer 23 and at least one material in the light-emitting layer 22 are combined to form an exciplex, where an S1 state energy level of the exciplex is less than an S1 state energy level of at least one material in the light-emitting layer 22, or a T1 state energy level of the exciplex is less than a T1 state energy level of at least one material in the light-emitting layer 22.

In one or more embodiments, the material in the electron blocking layer 23 and the material in the light-emitting layer 22 may be combined upon contact to form an exciplex, where the S1 state energy level of the exciplex is less than the S1 state energy level of the at least one material in the light-emitting layer 22, or the T1 state energy level of the exciplex is less than the T1 state energy level of the at least one material in the light-emitting layer 22, thereby reducing hole accumulation between the electron blocking layer 23 and the light-emitting layer 22, and the problem that turning-on of the organic light-emitting device 20 is liable to delay is better mitigated.

In one or more embodiments, at least one material in the electron blocking layer 23 and at least one material in the light-emitting layer 22 are combined to form an exciplex, where an S1 state energy level of the exciplex is less than an S1 state energy level of at least one material in the light-emitting layer 22, and a T1 state energy level of the exciplex is less than a T1 state energy level of at least one material in the light-emitting layer 22.

In one or more embodiments, as described above, the material in the light-emitting layer 22 includes the P-type material. In this case, the S1 state energy level of the exciplex is less than an S1 state energy level of the P-type material in the light-emitting layer 22, and the T1 state energy level of the exciplex is less than a T1 state energy level of the P-type material in the light-emitting layer 22. As such, accumulation of the exciplex between the electron blocking layer 23 and the light-emitting layer 22 can be reduced, and the capacitance formed between the electron blocking layer 23 and the light-emitting layer 22 can be decreased, thereby better mitigating the problem that turning-on of the organic light-emitting device 20 is liable to delay. The above S1 state energy level is a singlet state energy level, and the above T1 state energy level is a triplet energy level.

In one or more embodiments, at least one of the hole transport layer 21, the electron blocking layer 23, and the light-emitting layer 22 includes at least one of carbazole, triphenylamine, and spirofluorene, enabling better transport of holes between the hole transport layer 21, the electron blocking layer 23, and the light-emitting layer 22.

As described above, when the light-emitting layer 22 includes the P-type material, since the light-emitting layer 22 includes the P-type material, at least one of the hole transport layer 21, the electron blocking layer 23, and the P-type material in the light-emitting layer 22 includes at least one of carbazole, triphenylamine, and spirofluorene, and better transport of holes between the hole transport layer 21, the electron blocking layer 23, and the light-emitting layer 22 is implemented.

In one or more embodiments, the light-emitting layer 22 includes an N-type material, and the N-type material in the light-emitting layer 22 includes a nitrogenous heterocyclic derivative such as a triazine, a diazine, or a heterocyclic derivative containing oxygen, sulfur, etc., thereby improving the performance of the light-emitting layer 22 and improving the display effect of the display panel.

In one or more embodiments, the light-emitting layer 22 includes an N-type material, and the N-type material in the light-emitting layer 22 includes a triazine-containing nitrogen heterocyclic derivative triazine, a diazine-containing nitrogen heterocyclic derivative, a heterocyclic derivative containing oxygen, or a heterocyclic derivative containing sulfur, thereby improving the performance of the light-emitting layer 22 and improving the display effect of the display panel.

In one or more embodiments, the light-emitting layer 22 includes a P-type material, and an energy level difference between the HOMO energy level of the at least one material in the hole transport layer 21 and a HOMO energy level of the P-type material in the light-emitting layer 22 is less than or equal to 0.3 eV.

In one or more embodiments, the P-type material in the light-emitting layer 22 is used for transporting holes, and when the energy level difference between the HOMO energy level of the at least one material in the hole transport layer 21 and the HOMO energy level of the P-type material in the light-emitting layer 22 is less than or equal to 0.3 eV, hole accumulation between the light-emitting layer 22 and the hole transport layer 21 can be better reduced.

In one or more embodiments, it is possible that an energy level difference between the HOMO energy level of one or more materials in the hole transport layer 21 and the HOMO energy level of the P-type material in the light-emitting layer 22 is less than or equal to 0.3 eV.

In one or more embodiments, the light-emitting layer 22 further includes an N-type material, and an energy level difference between the HOMO energy level of the P-type material and a HOMO energy level of the N-type material in the light-emitting layer 22 is less than or equal to 0.6 eV.

In one or more embodiments, when the energy level difference between the HOMO energy level of the P-type material and the HOMO energy level of the N-type material in the light-emitting layer 22 is less than or equal to 0.6 eV, a capacitance difference formed inside the light-emitting layer 22 can be reduced, and the hole injection characteristics of the N-type material in the light-emitting layer 22 can be improved, thereby mitigating the problem of turning-on delay of the organic light-emitting device 20.

In one or more embodiments, a HOMO energy level of at least one material in the hole transport layer 21 is greater than a HOMO energy level of at least one material in the light-emitting layer 22.

In one or more embodiments, the HOMO energy level of the material in the hole transport layer 21 is lower, allowing holes to be transported more smoothly from the hole transport layer 21 to the light-emitting layer 22.

In one or more embodiments, it is possible that a HOMO energy level of one or more materials in the hole transport layer 21 is greater than a HOMO energy level of one or more materials in the light-emitting layer 22.

In one or more embodiments, as above, the light-emitting layer 22 includes the P-type material, and a HOMO energy level of at least one material in the hole transport layer 21 is greater than the HOMO energy level of the P-type material in the light-emitting layer 22, thereby enabling faster hole transport to the light-emitting layer 22.

In order to further illustrate the beneficial effects of the present application, Comparative example 1 and Comparative example 2, and Example 1, Example 2 and Example 3 are provided as shown in the table below.

| | Structure of | E0 | E1 | E2 | First frame |
|---|---|---|---|---|---|
| | film layers | (eV) | (eV) | (eV) | brightness (%) |
| Comparative | HT1/EBL1/GH1 | 0.31 | 0.1 | 0.21 | 25% |
| example 1 | | | | | |
| Comparative | HT1/EBL2/GH1 | 0.31 | 0.12 | 0.19 | 27% |
| example 2 | | | | | |
| Example 1 | HT1/EBL3/GH1 | 0.31 | 0.21 | 0.1 | 57% |
| Example 2 | HT1/EBL1/GH2 | 0.2 | 0.1 | 0.1 | 56% |
| Example 3 | HT1/EBL3/GH2 | 0.2 | 0.21 | −0.01 | 68% |

In the above table, HT represents a hole transport layer 21, EBL represents an electron blocking layer 23, and GH represents a light-emitting layer 22 of a green organic light-emitting device 20. Hole transport layers 21 represented by EBL1, EBL2, and EBL3 have different materials, and light-emitting layers 22 represented by GH1 and GH2 have different host materials, and the first difference E1 and the second difference E2 vary with examples. A molecular group of at least one material in HT1 is the same as a molecular group of at least one material in EBL3, and the same molecular group contained in HT1 and EBL3 is a spirofluorene group. E0 is an energy level difference between a HOMO energy level of at least one material in the hole transport layer 21 and a HOMO energy level of at least one material in the light-emitting layer 22. The first frame brightness is the luminance of the organic light-emitting device 20 in the first frame.

It can be seen from the comparison of example 3 in the above table with the other examples that when E0 is less than 0.3 eV and E1 is greater than E2, the first frame brightness of a display panel is significantly improved. It can be seen from the comparison of Comparative example 1 with Example 1 that when E1 is greater than E2, the first frame brightness of a display panel increases significantly from 25% to 57%. It can be seen from the comparison of Example 1 with Example 3 that when E0 is less than 0.3 eV, the first frame brightness of a display panel is significantly improved. It can be seen from the comparison of Example 2 with Example 3 that when E1 is greater than E2 and materials of the hole transport layer 21 and the electron blocking layer 23 contain the same molecular group, the first frame brightness of a display panel is significantly increased from 56% to 68%.

Therefore, when E0 is less than or equal to 0.3 eV, the display effect of the display panel can be effectively improved. When E1 is greater than E2, the display effect of the display panel can also be improved. When materials of the hole transport layer 21 and the electron blocking layer 23 contain the same molecular group, the display effect of the display panel can also be effectively improved.

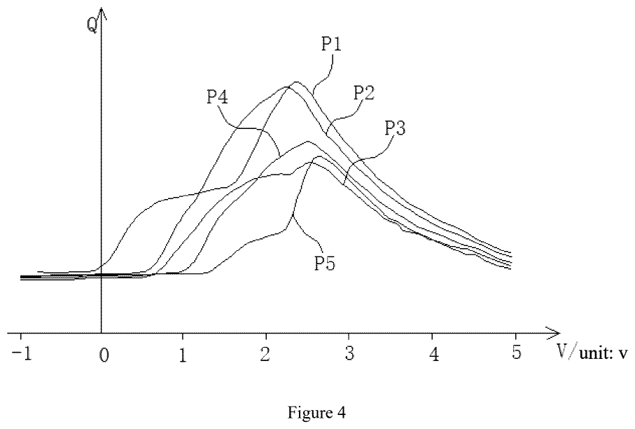

In the display panels provided in Comparative example 1 and Comparative example 2, and Example 1, Example 2 and Example 3, the organic light-emitting devices 20 all include the first electrode 30 and the second electrode 40 described above. A graph of voltage-capacitance curves of Comparative example 1 and Comparative example 2, and Example 1, Example 2 and Example 3 is shown in FIG. 4, which is obtained by taking voltages applied in Comparative example 1 and Comparative example 2, and Example 1, Example 2 and Example 3, and obtaining capacitances between the first electrodes 30 the second electrodes 40 in Comparative example 1 and Comparative example 2, and Example 1, Example 2 and Example 3. In this figure, P1 represents a voltage-capacitance curve of Comparative example 1, P2 represents a voltage-capacitance curve of Comparative example 2, P3 represents a voltage-capacitance curve of Example 1, P4 represents a voltage-capacitance curve of Example 2, and P5 represents a voltage-capacitance curve of Example 3.

As can be seen from FIG. 4, when the voltage is less than 3 V, for example, between 1 V and 2.5 V, the capacitance of Example 3 is always minimal. Therefore, the display panel of Example 3 can be turned on quickly. Since materials of the hole transport layer 21 and the electron blocking layer 23 in Example 1 contain the same molecular group, when the voltage is close to 3 V, the capacitances of Example 1 and Example 3 are close. Therefore, the same molecular group can well mitigate the problem of turning-on delay of the display panel.

Furthermore, as can be seen from the figure, when the voltage is varied from 0 to 5 V, the capacitances of Example 1, Example 2 and Example 3 are always less than those of Comparative Example 1 and Comparative Example 2. Therefore, it can be seen that when E0 is less than or equal to 0.3 eV, E1 is greater than E2, and materials of the hole transport layer 21 and the electron blocking layer 23 contain the same molecular group, the problem of turning-on delay of the display panel can also be effectively mitigated.

Therefore, when E0 is less than or equal to 0.3 eV, E1 is greater than E2, and materials of the hole transport layer 21 and the electron blocking layer 23 contain the same molecular group, not only can the brightness of the display panel be effectively improved, but also the problem of turning-on delay of the display panel can be effectively mitigated.

1. An organic light-emitting device, comprising:
a hole transport layer and a light-emitting layer that are arranged in a stacked manner, wherein an energy level difference between a HOMO energy level of at least one material in the hole transport layer and a HOMO energy level of at least one material in the light-emitting layer is less than or equal to 0.3 eV.

2. The organic light-emitting device according to claim 1, further comprising an electron blocking layer located between the hole transport layer and the light-emitting layer, wherein
there is a first difference between the HOMO energy level of the at least one material in the hole transport layer and a HOMO energy level of at least one material in the electron blocking layer; and
there is a second difference between the HOMO energy level of the at least one material in the electron blocking layer and the HOMO energy level of the at least one material in the light-emitting layer,
wherein the first difference is greater than the second difference.

3. The organic light-emitting device according to claim 2, wherein the light-emitting layer comprises a P-type material, and there is the second difference between the HOMO energy level of the at least one material in the electron blocking layer and a HOMO energy level of the P-type material in the light-emitting layer.

4. The organic light-emitting device according to claim 2, wherein
the at least one material in the hole transport layer and the at least one material in the electron blocking layer both comprise a specified molecular group;
or the at least one material in the electron blocking layer and the at least one material in the light-emitting layer both comprise a specified molecular group.

5. The organic light-emitting device according to claim 4, wherein
the at least one material in the hole transport layer, the at least one material in the electron blocking layer, and the at least one material in the light-emitting layer all comprise the specified molecular group.

6. The organic light-emitting device according to claim 5, wherein the specified molecular group comprises at least one of fluorene and derivatives thereof, triarylamine and derivatives thereof, carbazole and derivatives thereof, and heterocyclic derivatives.

7. The organic light-emitting device according to claim 4, wherein the light-emitting layer comprises a P-type material, and the at least one material in the electron blocking layer and the P-type material in the light-emitting layer both comprise the specified molecular group.

8. The organic light-emitting device according to claim 7, wherein the at least one material in the hole transport layer, the at least one material in the electron blocking layer, and the P-type material in the light-emitting layer all comprise the specified molecular group.

9. The organic light-emitting device according to claim 2, wherein a material in the electron blocking layer and a material in the light-emitting layer do not form an exciplex.

10. The organic light-emitting device according to claim 2, wherein a material in the electron blocking layer and a material in the light-emitting layer are combined to form an exciplex, wherein an S1 state energy level of the exciplex is less than an S1 state energy level of the at least one material in the light-emitting layer, or a T1 state energy level of the exciplex is less than a T1 state energy level of the at least one material in the light-emitting layer.

11. The organic light-emitting device according to claim 10, wherein the light-emitting layer comprises a P-type material, and the S1 state energy level of the exciplex is less than an S1 state energy level of the P-type material in the light-emitting layer.

12. The organic light-emitting device according to claim 10, wherein the light-emitting layer comprises a P-type material, and the T1 state energy level of the exciplex is less than a T1 state energy level of the P-type material in the light-emitting layer.

13. The organic light-emitting device according to claim 2, wherein at least one of the hole transport layer, the electron blocking layer, and the light-emitting layer comprises at least one of carbazole, triphenylamine, and spirofluorene.

14. The organic light-emitting device according to claim 13, wherein the light-emitting layer comprises a P-type material, and at least one of the hole transport layer, the electron blocking layer, and the P-type material in the light-emitting layer comprises at least one of carbazole, triphenylamine, and spirofluorene.

15. The organic light-emitting device according to claim 13, wherein the light-emitting layer comprises an N-type material, and the N-type material in the light-emitting layer comprises a triazine-containing nitrogen heterocyclic derivative triazine, a diazine-containing nitrogen heterocyclic derivative, a heterocyclic derivative containing oxygen, or a heterocyclic derivative containing sulfur.

16. The organic light-emitting device according to claim 1, wherein the light-emitting layer comprises a P-type material, and an energy level difference between the HOMO energy level of the at least one material in the hole transport layer and a HOMO energy level of the P-type material in the light-emitting layer is less than or equal to 0.3 eV.

17. The organic light-emitting device according to claim 16, wherein the light-emitting layer further comprises an N-type material, and an energy level difference between the HOMO energy level of the P-type material and a HOMO energy level of the N-type material in the light-emitting layer is less than or equal to 0.6 eV.

18. The organic light-emitting device according to claim 1, wherein the HOMO energy level of the at least one material in the hole transport layer is greater than the HOMO energy level of the at least one material in the light-emitting layer.

19. The organic light-emitting device according to claim 18, wherein a material in the light-emitting layer comprises a P-type material, and the HOMO energy level of the at least one material in the hole transport layer is greater than a HOMO energy level of the P-type material in the light-emitting layer.

20. A display panel, comprising:
an organic light-emitting device, comprising:
a hole transport layer and a light-emitting layer that are arranged in a stacked manner, wherein an energy level difference between a HOMO energy level of at least one material in the hole transport layer and a HOMO energy level of at least one material in the light-emitting layer is less than or equal to 0.3 eV.
